(19) United States
(12) Patent Application Publication
(10) Pub. No.: US 2010/0127180 A1
(43) Pub. Date: May 27, 2010

(54) SCINTILLATOR ARRAY AND A METHOD OF CONSTRUCTING THE SAME

(75) Inventors: Ronen Lifshitz, Rakefet Kfar Kehilati (IL); Adi Bolan, Haifa (IL)

Correspondence Address: William H. Dippert;Eckert Seamans Cherin & Mellott, LLC, U.S. Steel Tower, 600 Grant Street, 44th Floor, Pittsburgh, PA, 15219, US

(73) Assignee: CMT MEDICAL TECHNOLOGIES LTD., Yoqneam (IL)

(21) Appl. No.: 12/276,966

(22) Filed: Nov. 24, 2008

(51) Int. Cl. G01T 1/202; H01L 31/18

(52) U.S. Cl. 250/367; 438/68; 438/73; 250/370.11; 257/E31.001; 257/E21.598; 257/E21.599

(57) ABSTRACT

A pixilated scintillator, scintillator array and methods of fabricating the same are provided. The scintillator array comprises a grid having walls, a scintillator crystal packed between the walls, and a reflective coating provided between the walls and the scintillator crystal.

### FIELD OF THE INVENTION

The present invention relates to ionizing radiation imaging sensor. More particularly, the present invention relates to a sensor array such as a scintillator and a method of constructing the same.

### BACKGROUND OF THE INVENTION

Imaging of the human body in medical applications is often achieved by detection of X-rays in sensor materials. A sensor material is a material which, when interacting with X-ray photons, undergoes a physical change that is measurable by dedicated acquisition electronics. The combination of a sensor material and the corresponding acquisition electronics defines an X-ray detector or imager.

In a substantially direct-conversion X-ray detector, the sensor material converts X-ray energy to electrical charge, which is further processed by electronics processors. In a substantially indirect-conversion X-ray detector, the sensor material produces light, this is later converted to electrical charge.

The sensor materials used in indirect-conversion X-ray detectors are called scintillators. A scintillator is a material that essentially converts X-ray energy into light. Light is further absorbed by an attached photodiode and an electrical signal is produced. At times, this signal represents the total electric-charge generated by the arrival of a single X-ray photon (Single Photon Counting), at times the integrated charge due to the arrival of a plurality of photons within a preset time interval.

Further, imaging requires the measurement of two-dimensional X-ray intensity distribution. This is commonly achieved by the use of position sensitive detectors. Most of the X-ray two-dimensional-imaging detectors use a scintillator that is either a continuous sheet or a micro-structured one (e.g. column-grown CsI(Tl) bulk CsI(Tl)). The disadvantage of both is that, in the case of a scintillator, light can travel to a photodiode that is not the one closest to its origin. This light dissipation leads to two-fold image deterioration effect: (a) drop in spatial sensitivity (i.e. blurring), and (b) lower light intensity collectable per pixel per X-ray photon. The latter is critical for a Single Photon Counting detector.

In the case of multiple slice CT scanners, scintillator arrays are built by coupling arrays of scintillator elements—i.e. pixelated scintillator—to arrays of photodiode elements. The arrays of Scintillator elements are constructed so as to have septa made of light reflecting material in between the elements and on the surface facing the radiation source and opposing the photodiode. Thus, the septa improve scintillator performance by both preventing light from dissipating among adjacent pixels, and by efficiently guiding light from its point of origin to the closest photodiode. Typically, the dimensions of scintillator elements for CT scintillators are of 1 mm or more. The fabrication methods used for making these scintillators arrays are optimal for this size of elements and are not suitable for constructing arrays of substantially smaller elements.

Furthermore, in scintillator array, one must take into account the radiation absorption efficiency—namely the fill-factor. The efficiency (i.e. stopping power) of a scintillator is proportional to its density. When introducing an array of elements that are separated from each other, the effective density drops, and so does the stopping power. This fact is usually described as a fractional fill-factor, which means that the given material only partially fills the total of its designated volume. Thus, in order to maintain high efficiency, the gaps between adjacent elements must be kept minimal. It is in the scope of this invention to present methods of manufacturing high-pitch pixelated scintillators that maintain a high fill-factor by introducing very fine gaps between adjacent elements.

There are several known in the art techniques for cutting scintillators. U.S. Pat. No. 6,245,184 titled “Method of Fabricating Scintillators for Computed Tomograph System” by Riedner et al, filed on 1997 discloses a method of fabricating scintillators using an inside diameter saw. The problem of fabricating relatively small scintillator units remains unsolved in the description.

In other X-ray imaging applications requiring higher resolution it is common to use a plate of columnary grown CsI scintillator material coupled to array of photodiode cells where the photodiode cells size is typically 0.15 mm×0.15 mm or even smaller. Lateral light spread within the scintillator plate is avoided by the columnar structure of the material. However, light spread cannot be totally avoided for thicker CsI plate, thus limiting the thickness of the plate or the achievable resolution. The thickness of the plate is strongly related to the dose efficiency of the device. Further, colmunary grown CsI is less dense and less radiation absorbing than solid crystal of CsI.

U.S. Pat. No. 6,328,027 titled “Method for Precision Cutting of Soluble Scintillator Materials” by Persyk et al filed on 1999 discloses a method that includes the steps of providing a first run of a moving filament in operative proximity to cut the scintillator materials, concurrent with wetting at least the first run length of the moving filament with organic solvent, and engaging the wetted first run with the soluble scintillator materials for a time sufficient to create a kerf having cut surfaces with solvent thereon, with the kerf cut surfaces dissolved to reshape the kerf corners, and without the formation of surface hydrates. The invention is using a moving strip which locally melts the scintillator and removes the melt from the bulk.

U.S. Pat. No. 7,054,408 titled “CT Detector Array Having Non Pixelated Scintillator Array” by Jiang et al filed on 2003 discloses a directed to a non-pixelated scintillator array for a CT detector as well as an apparatus and method of manufacturing same. The invention is only aimed to provide non pixelated scintillator array and is not addressing pixelated structure or fabrication. Moreover, the problem of fabricating relatively small scintillators units remains unsolved in the description.

U.S. Pat. No. 7,053,380 titled “X-ray Detector and Method for Producing X-ray Detector” by Homma et al filed on 2003 discloses An X-ray detector comprising a scintillator layer provided for each pixel and adapted for converting X radiation into light, a storage capacitor for storing, as electric charge, the light converted in the scintillator layer, and a partition layer partitioning the adjoining scintillator layers provided to the respective pixels. While the invention discloses a pixelated scintillator, the means of pixelization are not discussed in detail. The focus is rather set to introducing an additional fluorescent material, having different optical properties, as a separator between adjacent scintillating pixels. U.S. Pat. No. 7,329,875 titled “Detector Array for Imaging System and Method of Making Same” by McEvoy et al filed on 2004 discloses a method of manufacturing a detector array for an imaging system, the method comprising providing a pixelated scintillator having a plurality of lost molded pixels comprising a scintillator material adapted to detect radiation. The invention is solely based on forming the scintillator material in a mold, and then discarding the mold.

There is a need in the radiation imaging industry to provide high pitch pixelated arrays of scintillator elements so as to enable high resolution imaging while keeping a high efficiency/fill-factor and thus using minimum X-ray exposure for the subject.

### SUMMARY OF THE INVENTION

It is an object of the present invention to provide a physical structure of improved scintillator arrays.

It is an object of the present invention to provide a method of fabricating the improved scintillator arrays. The method that is used in the present invention avoids contradicting requirements from the materials used.

It is another object of the present invention to provide a physical structure of improved scintillator arrays defining parallelepiped scintillating structures of sizes such as 0.5 mm or less and septa walls of a few microns to tens of microns in thickness.

It is yet another object of the present invention to provide a physical structure having parallelepiped voids defined by the septa walls, i.e. grid, that can then be filled with active sensing material (e.g. CsI(Tl) scintillator. Examples of other common scintillating materials that can be used are NaI(Tl), ZnS, BGO, GOS, LSO and more. These are all inorganic crystals, yet also organic crystals can be used. Liquid scintillators can also be used for some parts of this invention.

It is another object of the present invention to use a grid that is filled with active sensing material, in which case anti-scatter grid becomes an integral part of the scintillator.

It is another object of the present invention to use empty grids as anti-scatter grids, installed on top of a scintillator array. This further allows exact registration between empty grid voids and scintillator pixels, so as to prevent efficiency drop due to the usage of an anti-scatter grid.

Yet, it is an object of the present invention to allow stacking of such physical structures, both pixelated scintillator/s and empty grid/s for anti-scatter, in order to reach high thicknesses at difficult geometrical aspect ratios.

An additional object of the present invention is to allow accurate 4-way tiling of several structures in order to cover indefinitely large areas (planar or not) without generating gaps in-between tiles.

Therefore, it is provided in accordance with a preferred embodiment of the present invention a pixelated scintillator comprising pixels of less than 1 mm.

Furthermore and in accordance with another preferred embodiment of the present invention, wherein the pixels are less than 0.5 mm.

Furthermore and in accordance with another preferred embodiment of the present invention, the pixels are fabricated using dicing technology.

Furthermore and in accordance with another preferred embodiment of the present invention, said dicing technology includes saw dicing, Silicone wafer dicing, laser dicing, or laser ablation.

It is also provided in accordance with yet another preferred embodiment of the present invention, a scintillator array comprising:

a grid having walls;

a scintillator crystal packed between said walls;

a reflective coating provided between said walls and said scintillator crystal

wherein said grid is made of a material selected from a group of materials such as metal, ceramic, polymer, adhesive.

Furthermore and in accordance with another preferred embodiment of the present invention, said grid is a copper grid.

Furthermore and in accordance with another preferred embodiment of the present invention, said reflective coating is made of a material selected from a group of materials such as Silver (Ag), Gold (Au), Aluminum (Al), Rhodium (Rh), Titanium Dioxide (TiO₂), Barium Sulfate (BaSO₄), or a combination thereof.

Furthermore and in accordance with another preferred embodiment of the present invention, said scintillator crystal is of organic or inorganic crystals.

Furthermore and in accordance with another preferred embodiment of the present invention, said scintillator crystal is made of material selected from a group of scintillating materials such as NaI(Tl), ZnS, BGO, GOS and LSO.

Furthermore and in accordance with another preferred embodiment of the present invention, said scintillator crystal is CsI(Tl) crystal.

Furthermore and in accordance with another preferred embodiment of the present invention, the scintillator crystal is fully enclosed within the walls of the grid.

Furthermore and in accordance with another preferred embodiment of the present invention, the array further comprising a (3D) antiscatter grid accurately registered with said array.

Furthermore and in accordance with another preferred embodiment of the present invention, the array further comprising a light transmitting medium for optical coupling provided within a gap between said walls and said scintillator crystal.

Furthermore and in accordance with another preferred embodiment of the present invention, said light transmitting medium has a refractive index that substantially equals a refractive index of the scintillator crystal.

Furthermore and in accordance with another preferred embodiment of the present invention, said refractive index resembles a refractive index of approximately 1.8.

Furthermore and in accordance with another preferred embodiment of the present invention, a top surface of the array is coated with reflecting material whereas a bottom surface of the array is used for coupling to light sensor array.

It is also provided in accordance with an additional embodiment of the present invention, a method for fabricating a scintillator array comprising:

providing a grid having voids;

coating said grid with reflective material; and

providing a scintillator material to within said voids.

Furthermore and in accordance with another preferred embodiment of the present invention, providing a scintillator crystal to within said voids comprises:

dicing using silicone wafer dicing technologies parallel and vertical trenches in said scintillator material so as to receive a trenched scintillator; and

pressing said grid to within said trenched scintillator.

Furthermore and in accordance with another preferred embodiment of the present invention, the method further comprising filling a space between said grid and said scintillator material with light reflecting material.

Furthermore and in accordance with another preferred embodiment of the present invention, the method further comprises filling a space between said grid and said scintillator crystal with light transmitting material having an index of refraction substantially close to an index of refraction of the scintillator material.

Furthermore and in accordance with another preferred embodiment of the present invention, said providing a scintillator material to within said voids comprises evaporating scintillator material onto said grid so as to fill the grid voids with scintillator material.

Furthermore and in accordance with another preferred embodiment of the present invention, the method further comprises grinding or polishing extra scintillator material so as to achieve flat top and bottom surfaces.

Furthermore and in accordance with another preferred embodiment of the present invention, said providing a scintillator material to within said voids comprises growing scintillator material from a solution into said grid so as to fill the grid voids with scintillator material.

Furthermore and in accordance with another preferred embodiment of the present invention, the method further comprises grinding or polishing extra scintillator material so as to achieve flat top and bottom surfaces.

Furthermore and in accordance with another preferred embodiment of the present invention, said providing a scintillator material to within said voids comprises growing scintillator material from a melt into said grid so as to fill the grid voids with scintillator material.

Furthermore and in accordance with another preferred embodiment of the present invention, the method further comprises grinding or polishing extra scintillator material so as to achieve flat top and bottom surfaces.

Furthermore and in accordance with another preferred embodiment of the present invention, said providing a scintillator material to within said voids comprises pressing said grid into scintillator material plate under high temperature conditions so as to fill the grid voids with scintillator material, yet avoiding a complete meltdown of the scintillator material.

Furthermore and in accordance with another preferred embodiment of the present invention, the method further comprises grinding or polishing extra scintillator material so as to achieve flat top and bottom surfaces.

Furthermore and in accordance with another preferred embodiment of the present invention, said providing a grid having voids comprises:

dicing using a wafer dicing technology parallel and vertical trenches in said scintillator material so as to receive a trenched scintillator; and

filing the trenched with adhesive material that forms said grid.

Furthermore and in accordance with another preferred embodiment of the present invention, said providing a scintillator material to within said voids comprises:

providing powder made of scintillator material;

pressing said powder of scintillator material into voids of said grid so as to fill the grid voids with scintillator material; and

pressing said powder into solid material by the effect of pressure and high temperature.

Furthermore and in accordance with another preferred embodiment of the present invention, the method further comprises grinding or polishing extra scintillator material so as to achieve flat top and bottom surfaces.

### BRIEF DESCRIPTION OF THE DRAWINGS

In order to better understand the present invention and appreciate its practical applications, the following Figures are attached and referenced herein. Like components are denoted by like reference numerals.

It should be noted that the figures are given as examples and preferred embodiments only and in no way limit the scope of the present invention as defined in the appending Description and Claims.

FIG. 1 illustrates a grid in accordance with a preferred embodiment of the present invention.

FIG. 2 illustrates a scintillator array in accordance with another preferred embodiment of the present invention.

FIG. 3 illustrates a cross sectional view of a physical structure of improved scintillator array in accordance with a preferred embodiment of the present invention.

FIG. 4 illustrates an isometric view of stack of grid and scintillator grid in accordance with a preferred embodiment of the present invention.

FIG. 5 illustrates an isometric view of planar and of non-planar scintillator in a detector in accordance with a preferred embodiment of the present invention.

FIG. 6 illustrates stages of manufacturing of scintillator grid in accordance with a preferred embodiment of the present invention.

FIG. 7 illustrates a pixelated scintillator in accordance with another preferred embodiment of the present invention.

FIG. 8 illustrates a pixelated scintillator in accordance with yet another preferred embodiment of the present invention.

### DETAILED DESCRIPTION OF THE PREFERRED EMBODIMENTS

The present invention provides a new method for manufacturing a pixelated scintillator at a high pitch and a high fill factor, stopping power, and efficiency.

The present invention provides means of optimizing the method for maximal light output and minimal dissipation of light between adjacent pixels.

In addition, it is provided means of using this approach to provide improved scatter-radiation rejection at the detector entrance, as either an integral part of the scintillator or an additional assembly.

A pixelated scintillator is necessary for both improving spatial imaging resolution and increasing light output per pixel. And yet, pixelated scintillators and methods for producing them are available for pixel sizes that are inadequate for high resolution X-ray imaging. For example, scintillator pixels used in Computed Tomography (CT) are typically 1 mm in size. The methods for making such pixels are not suitable for higher resolution imaging, since the relatively large spaces between the pixels would decrease the fill factor, i.e. the efficiency, so that patient exposure to radiation is not properly exploited. This invention will present methods for producing and optimizing high pitch and high fill-factor pixelated scintillators.

Another source for imaging deficiency is X-ray radiation scattering. X-ray imaging is based on changes of X-ray attenuation in the subject under study (e.g. a patient). The image consists of different shades-of-gray, which correspond to the amount of radiation that penetrated and survived the passage through the patient, and detected by the imaging device. Thus, X-ray photons that are deflected from their original trajectory, i.e. scattered, cause deterioration of imaging quality. In order to optimize for imaging quality, anti-scatter grids are commonly used. These are X-ray attenuating objects that are placed right above the detector entrance plane. They attenuate a significant fraction of X-rays that are not directed perpendicular to the detector plane. However, since their structure is uncorrelated with the detector internal structure, anti-scatter grids also partially attenuate radiation that is directed towards the detector. As a result, while improving image quality, the use of anti-scatter grids often leads to increasing the patient exposure to radiation. This invention will present a method of using an anti-scatter grid that is fully registered to the pixelated structure of the scintillator, thus the need for dose increase is minimized. In addition, the anti-scatter grid may be an integral part of the pixelated scintillator.

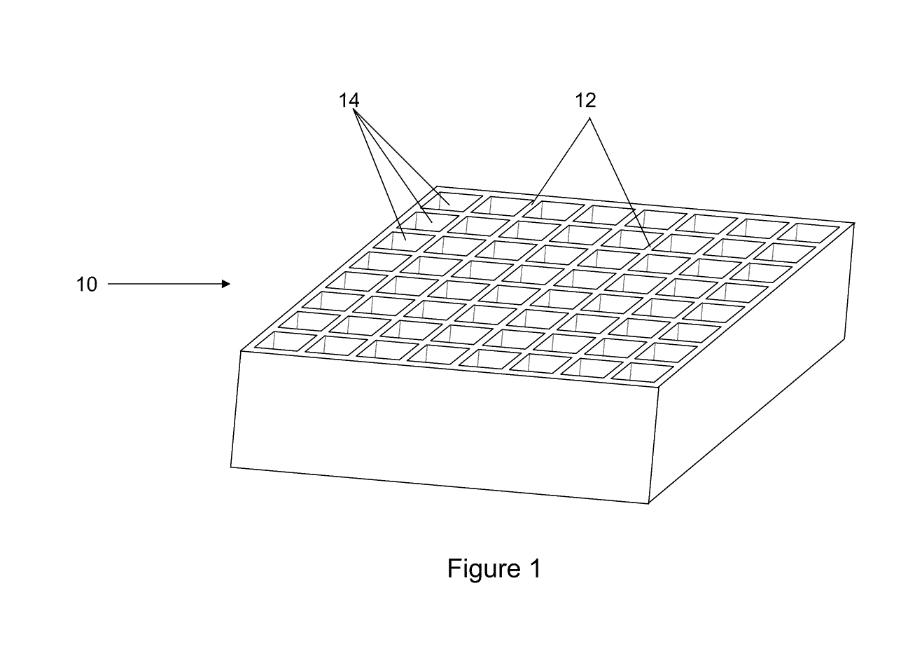

Reference is made to FIG. 1 illustrating grid in accordance with a preferred embodiment of the present invention. A grid 10 is a physical structure of substantially 0.6 mm in thickness (i.e. pixel depth). The septa 12 are about 0.030 mm in thickness; they separate between adjacent pixel voids 14. In this preferred embodiment, the combination of voids 14 and septa 12 dimensions dictates a repeatable cell unit 250 μm in size, thus the pitch is 4 pixels per 1 mm in both X and Y directions. Grid 10 is open on both faces, yet a cover can be added to any of the faces in some embodiments. Grid 10 can be made of copper or from other materials, either metal or ceramic or plastic or polymer. For optimizing light output per pixel, it is preferred that grid 10 walls are coated with light reflecting material, i.e. reflector. Reflector coating can be any type of commonly used materials that optimize light reflection, either specular or diffusive, for example: Silver (Ag), Gold (Au), Aluminum (Al), Rhodium (Rh), Titanium Dioxide (TiO₂), Barium Sulfate (BaSO₄), or any other material/alloy/mixture.

Grid 10 can also be made from materials that allow high-precision production using lithography technologies, for example photo-resist material such as SU8. Applying a reflector coating is preferred in this case as well.

Grid 10 can be made of such materials that also serve as absorbers of X-ray photons that are scattered between adjacent pixels, such as Lead, Bismuth, Bismuth-Tin, and other heavy substances or alloys.

According to one aspect of the present invention, grid 10 is first coated with a thin Ni layer and then preferably with a thin Ag layer to maximize wall reflectivity in the visible region of the spectrum. The Ni layer prevents migration of Ag atoms into the grid wall. Parylene coating is further applied to provide chemical isolation between reflecting layer and scintillating material or air, depending on the embodiment.

Smooth and thin grid walls maximize light-reflection, maximize the active sensor volume (fill factor), and confine visible light to the vicinity of the interaction region, thus preventing cross talk between cells.

It should be mentioned that any other material might be used for the grid or for its coating, depending on the desired optimization.

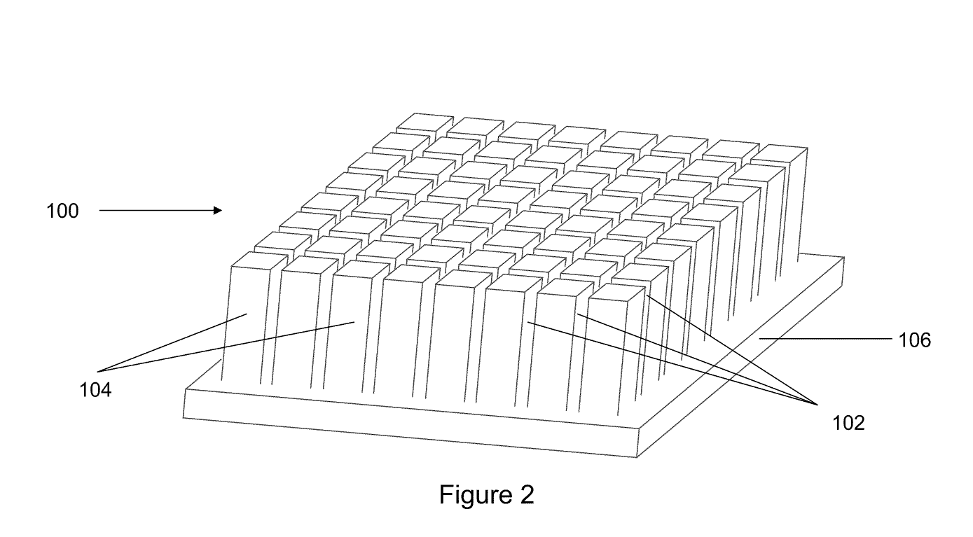

Reference is now made to FIG. 2 illustrating a scinitillator array in accordance with a preferred embodiment of the present invention. A CsI(Tl) crystal 100 as an example, substantially 0.8 mm thick, is divided into blocks by dicing substantially 0.6 mm of its depth, 0.050 mm of its width. Trenches 102 are formed along a rectangular structure with a corresponding x and y pitch as the grid structure as shown in FIG. 1. Trenches 102 are fabricated using silicon wafer dicing technologies in which mechanical sawing or laser cutting or laser ablation can be applied. These technologies allow high quality fabrication of large sample sizes and quantities. Trenches can be very fine (down to few microns), thus a high fill factor is achievable also for large arrays of small pixels. For example, 25 μm trenches in a 250 μm pitch gives rise to a fill factor of about 80%. It should be noted that the adaptation of silicon wafer dicing technologies for scintillator machining/trenching/pixelization is a significant technological advancement.

After dicing, scintillator columns 104 are provided on a supporting portion 106 that remains intact beneath the columns. Then, the scintillator array is registered with a matching grid and the two are merged (walls into trenches) by applying mild pressure as will be shown hereinafter.

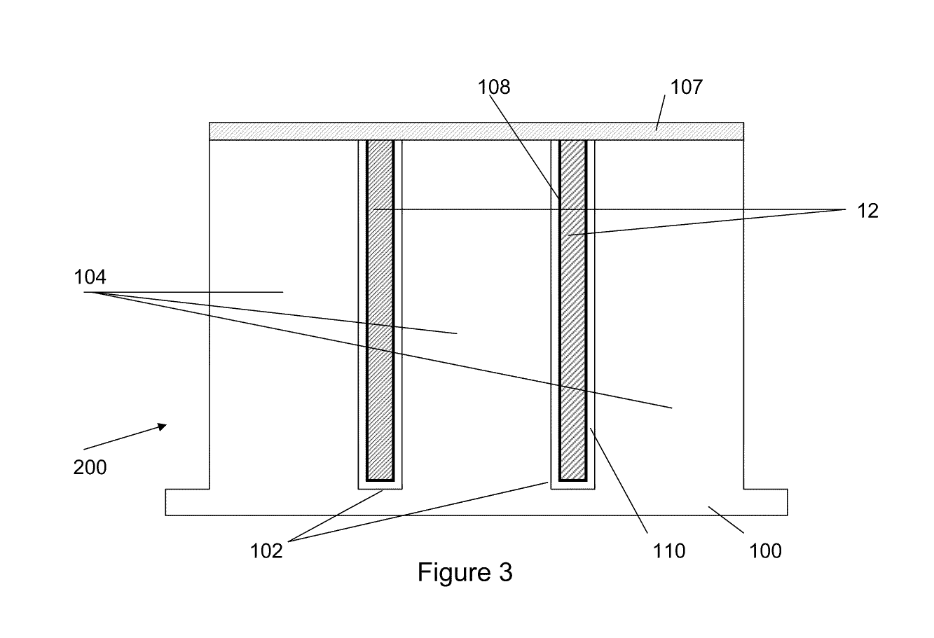

Reference is now made to FIG. 3 illustrating a cross sectional view of a physical structure of improved scintillator array in accordance with a preferred embodiment of the present invention. Scintillator array 200 comprises both scintillator columns 104 with trenches 102 between them, while walls 12 of grid 10 are pressed within trenches 102. In this figure, coating 108 can be seen, covering walls 12. The top-face light reflecting layer 107 is shown. Layer 107 can then be applied on the top face of the combined array, the face directing towards the incident radiation, opposite to the photo sensor array. It should be noted that, in this case, the reflecting layer must have minimal impact on the incident radiation. This is achieved by using light (low Z) materials and/or thin layers.

Bottom portion of the array will be removed by lapping/polishing action up to the level of the grid septa. The polishing action is performed in any of the manufacturing methods that are mentioned herein after as optional methods of sensor array manufacturing.

The gap 110 between the grid and the walls of the trenches is filled with light transmitting material that is suitable for optical phase matching between the scintillating material and the reflective coating of the grid. Such material is the adhesive #301-2 from Epoxy Technology, which is widely used in the medical industry. This substance is used to fill the gaps between walls 12 and columns 104.

There are several methods by which a scintillator grid is manufactured. The order of steps that are being taken can be changed as well as the order in which the elements are being produced or arranged together.

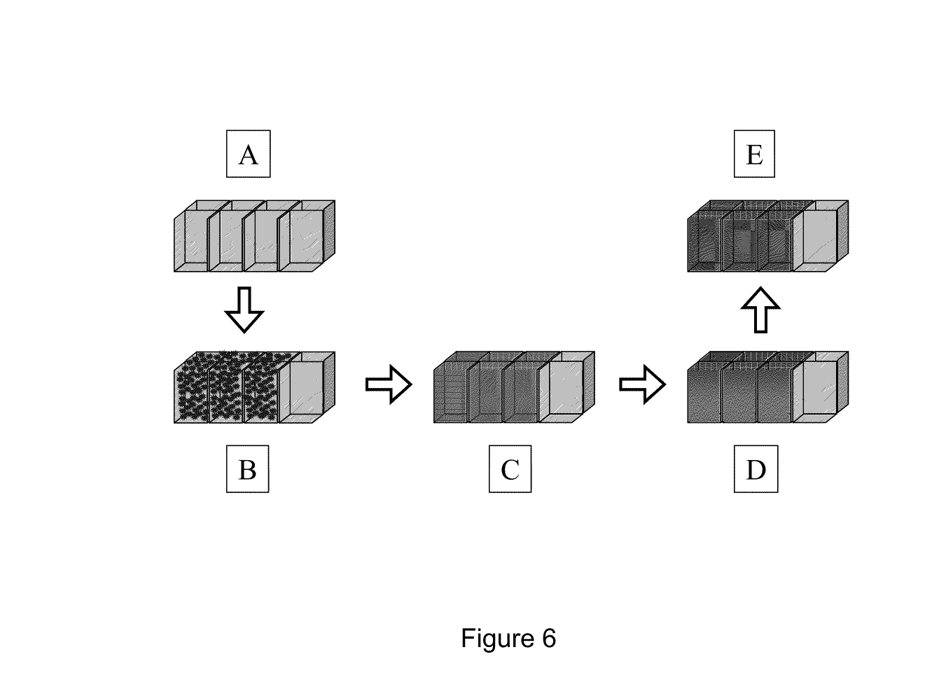

Reference is now made to FIG. 6 illustrating stages of manufacturing of scintillator grid in accordance with a preferred embodiment of the present invention. Empty grid A is being filled with scintillator powder B such as CsI(Tl) powder. Scintillator powder B is pressured into the void of the empty grid and inserted into a furnace of high temperature. The scintillator powder is melted C in a controlled atmosphere and than cooled down in a controlled environment allowing high quality crystallization D. A grid with crystallized scintillator E is achieving maximum material density and therefore highest X-ray attenuation.

The remaining voids between particles, if exist, may be filled with an optical liquid. In one embodiment of the present invention, the filling material is pressed within the gap and sintered to achieve maximum material density and therefore highest X-ray attenuation.

In yet another embodiment, the grid is filled with melted scintillator, which is then being left to cool and solidify in the grid cells. The grid can be filled and/or covered with scintillator powder such as CsI(Tl) powder, or solid scintillator. Then, it can be inserted into a controlled atmosphere furnace for meltdown. Atmosphere control is necessary (vacuum or inert gas) for preventing possible chemical damage to the reflectivity of grid walls while heating, such as oxidation of silver coating. When the scintillator melting point is reached, the powder melts and completely fills the grid voids. Scintillator cool-down is to be carefully controlled, since it governs the scintillator crystallization mode, according to the type of scintillating material used. The cooling method can be adapted from the known art of crystal growing from melt, such as the kyropolous method.

In another embodiment, the scintillator is manufactured by dipping the grid into CsI(Tl) water solution and the scintillator is directly grown from water solution in the grid voids. The grid is first protected by thin coating (such as Parylene), to prevent chemical reaction with the solution medium. Grid is inserted into a vessel filled with scintillator solution. By introducing an array of scintillator crystal seeds, a single seed per grid void, mono-crystal growth occurs directly in the grid.

In yet another embodiment, the scintillator is built into the voids by CsI(Tl) vapor deposition in vacuum. The grid may be attached to a substrate, having a single crystallization seed implanted at each void. This assembly is exposed to scintillating material in vapor form (such as Caesium, Iodide, and Thallium in the right concentrations for CsI(Tl)) at the right conditions, normally in vacuum and some thermal excitation. Such processes are common to those who master crystal growing. Eventually, the vapor atoms are implanted onto the crystal seeds, and layers of scintillating crystal are deposited directly into the grid.

In accordance with another aspect of the present invention, the manufacturing process involves using pixelated scintillator as described above, but without the grid. This may be due to considerations such as lowering the cost, and/or simplifying the production process. According to this concept, the trenches of a pixelated scintillator are filled with adhesive material that hardens within the trenches and eventually acts as a grid.

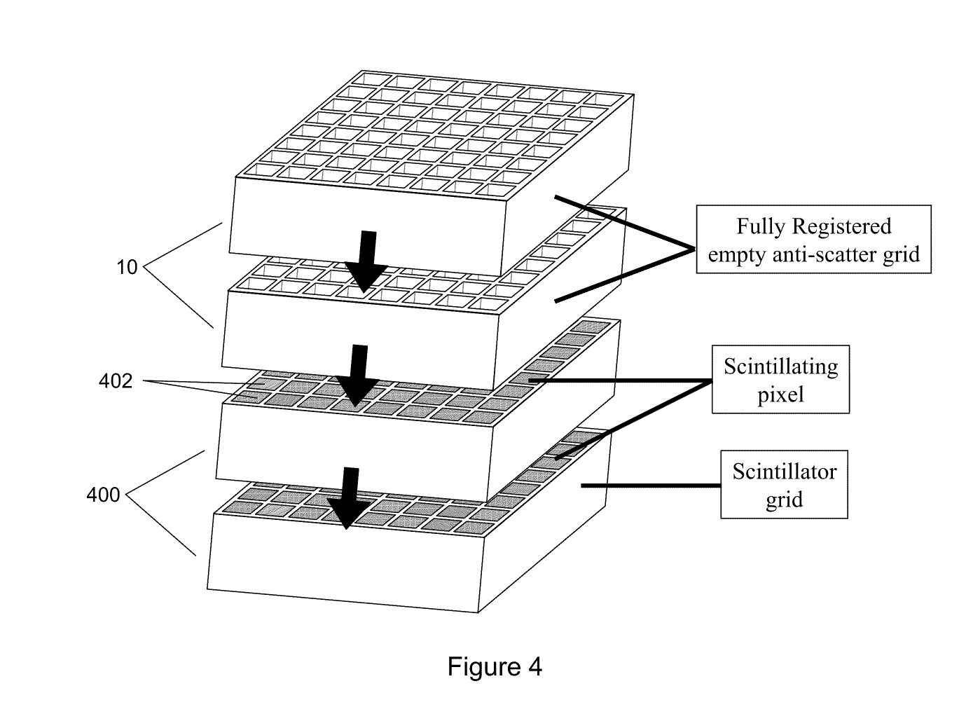

Reference is now made to FIG. 4 illustrating an isometric view of stack of grid and scintillator grid in accordance with a preferred embodiment of the present invention. As mentioned hereinbefore, a fully registered anti scatter grid 10 is stacked onto a scintillating grid 400 that comprises scintillating pixels 402. The correspondence between the anti scatter empty grid pitch and the scintillator pixels allows full registration of all components, and thus a higher efficiency relative to other known in the art non-registered anti-scatter grid assemblies.

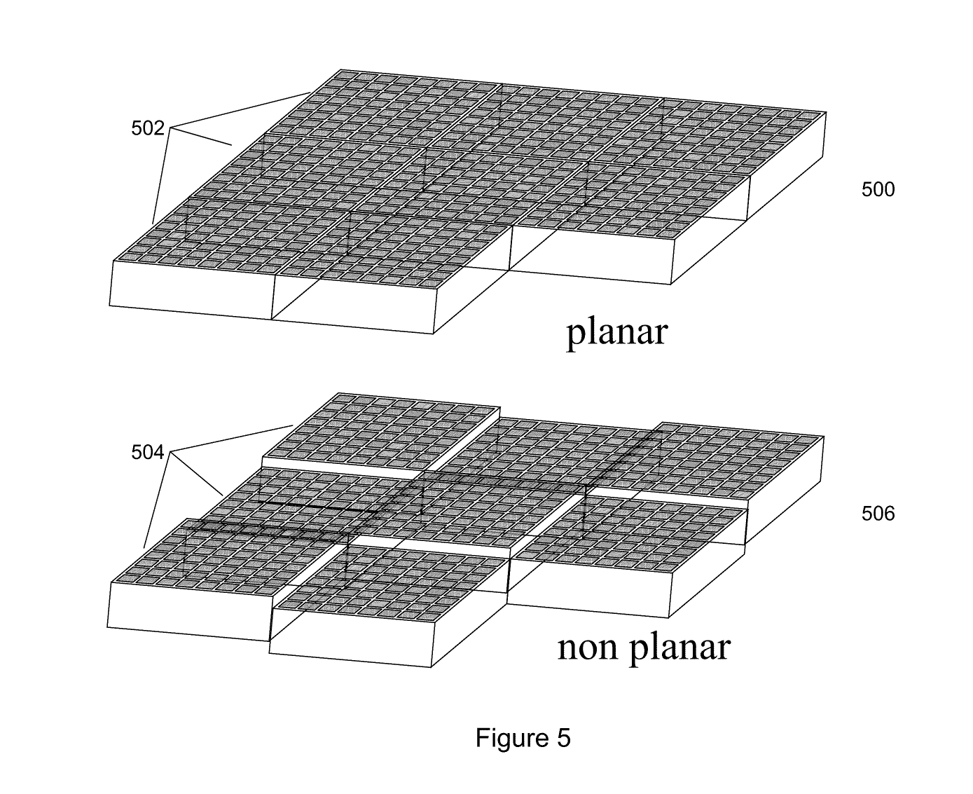

Reference is now made to FIG. 5 illustrating an isometric view of planar and of non-planar tiling of scintillators in a detector, in accordance with a preferred embodiment of the present invention. A planar scintillator 500 comprises a plurality of scintillator grids 502 that are aligned on a straight surface. This is a preferred situation. In some applications non planar arrangement may be required due to either assembly or size limitations of a detector's geometry. As an example, scinitillator grids 504 are positioned on a non planar surface, having gaps between one another to give a non planar scintillator 506.

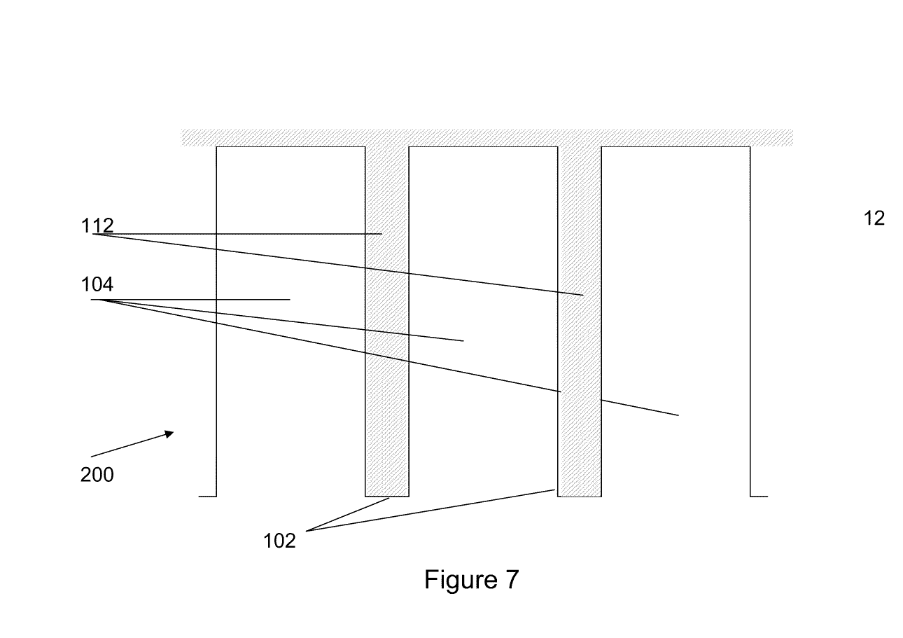

Reference is now made to FIG. 7 illustrating a pixelated scintillator in accordance with another preferred embodiment of the present invention. In a preferred embodiment, the pixelated scintillator is completely covered by light reflecting adhesive, such as silver-filled epoxy or white reflecting epoxy (for example—based on TiO₂ and/or BaSO₄ as mentioned above). The reflective adhesive may be enriched with heavier materials (such as Tantalum-Ta, Bismuth-Bi, or Lead-Pb), so that soft X-rays are attenuated and cross talk via X-rays is prevented. The voids 102 that separate between scintillating columns 104 are filled with a reflecting adhesive 112. The reflecting cover of the pixelated scintillator is made of the same substance. Thus, the adhesive serves as the grid in different embodiments mentioned above.

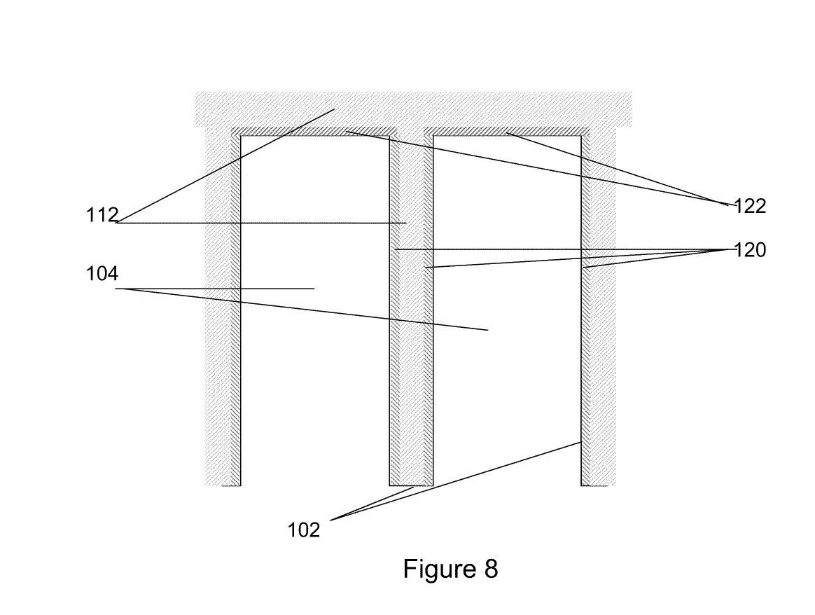

Reference is now made to FIG. 8 illustrating a pixelated scintillator in accordance with yet another preferred embodiment of the present invention. In another embodiment, the pixelated scintillator is first coated with a highly efficient light-reflecting layer, and then covered by an adhesive. Scintillator columns 104 are first treated to improve their surface quality. Then, columns 104 are coated with special wall coating 120 and cover coating 122. These two coatings may be of either identical or different types, according to the optimization of light reflecting performance. After coatings 120 and 122 are applied, the trenches are completely filled with an adhesive 112. An example of such high efficiency reflector coating is Aluminum (Al) or Silver (Ag) that may be applied using Sputtering. Such a process, together with the above-mentioned surface quality improvement, results in a high quality mirror on the internal surfaces of each scintillating column 104.

It should be noted that, special case of the two coatings 120 and 112 being different is using Aluminum or Silver sputtering (or other mirror-like) on both walls and cover, and then removing the cover coating and thus leaving mirror reflectors on the walls and a plain adhesive reflector coating on the cover. Adhesives usually introduce diffusive near-Lambertian light reflection (i.e. not mirror-like), that biases light reflection towards the opposite face of the scintillating column.

According to yet another embodiment of the present invention, a diffusive reflector rather than mirror-like reflector is introduced as the cover of a scintillating column—biases light into the direction of the column floor (i.e. bottom), where a photo-sensor should be coupled.

In any one of the cases and manufacturing methods, a top surface of the scintillator array is coated with reflecting material whereas a bottom surface of the array is used for coupling to photodiode array.

It should be noted that according to the method of the present invention, the compatibility with automated, as opposed to manual, production methods is addressed.

It should be noted that the dimensions given herein are solely exemplary dimensions. Other embodiments are possible with different cell patterns. The examples by no means limit the scope of the present invention.

It should be clear that the description of the embodiments and attached Figures set forth in this specification serves only for a better understanding of the invention, without limiting its scope as covered by the following Claims.

It should also be clear that a person skilled in the art, after reading the present specification can make adjustments or amendments to the attached Figures and above described embodiments that would still be covered by the following Claims.

What is claimed:

1. A pixelated scintillator comprising pixels of less than 1 mm.

2. The scintillator as claimed in claim 1, wherein the pixels are less than 0.5 mm.

3. The scintillator as claimed in claim 1, wherein the pixels are fabricated using dicing technology.

4. The scintillator as claimed in claim 3, wherein said dicing technology includes saw dicing, Silicone wafer dicing, laser dicing, or laser ablation.

5. A scintillator array comprising:
a grid having walls;
a scintillator crystal packed between said walls;
a reflective coating provided between said walls and said scintillator crystal.

6. The array as claimed in claim 5, wherein said grid is made of a material selected from a group of materials such as metal, ceramic, polymer, adhesive.

7. The array as claimed in claim 6, wherein said grid is a copper grid.

8. The array as claimed in claim 5, wherein said reflective coating is made of a material selected from a group of materials such as Silver (Ag), Gold (Au), Aluminum (Al), Rhodium (Rh), Titanium Dioxide (TiO₂), Barium Sulfate (BaSO₄), or a combination thereof.

9. The array as claimed in claim 5, wherein said scintillator crystal is of organic or inorganic crystals.

10. The array as claimed in claim 5, wherein said scintillator crystal is made of material selected from a group of scintillating materials such as NaI(Tl), ZnS, BGO, GOS and LSO.

11. The array as claimed in claim 5, wherein said scintillator crystal is CsI(Tl) crystal.

12. The array as claimed in claim 5, wherein the scintillator crystal is fully enclosed within the walls of the grid.

13. The array as claimed in claim 5, further comprising a (3D) antiscatter grid accurately registered with said array.

14. The array as claimed in claim 5, further comprising a light transmitting medium for optical coupling provided within a gap between said walls and said scintillator crystal.

15. The array as claimed in claim 14, wherein said light transmitting medium has a refractive index that substantially equals a refractive index of the scintillator crystal.

16. The array as claimed in claim 15, wherein said refractive index resembles a refractive index of approximately 1.8.

17. The array as claimed in claim 5, wherein a top surface of the array is coated with reflecting material whereas a bottom surface of the array is used for coupling to light sensor array.

18. A method for fabricating a scintillator array comprising:
providing a grid having voids;
coating said grid with reflective material;
providing a scintillator material to within said voids;

19. The method as claimed in claim 18, wherein providing a scintillator crystal to within said voids comprises:
dicing using silicone wafer dicing technologies parallel and vertical trenches in said scintillator material so as to receive a trenched scintillator; and
pressing said grid to within said trenched scintillator.

20. The method as claimed in claim 18 further comprising filling a space between said grid and said scintillator material with light reflecting material.

21. The method as claimed in claim 18 further comprising filling a space between said grid and said scintillator crystal with light transmitting material having an index of refraction substantially close to an index of refraction of the scintillator material.

22. The method as claimed in claim 18 wherein said providing a scintillator material to within said voids comprises evaporating scintillator material onto said grid so as to fill the grid voids with scintillator material.

23. The method as claimed in claim 22, further comprising grinding or polishing extra scintillator material so as to achieve flat top and bottom surfaces.

24. The method as claimed in claim 18, wherein said providing a scintillator material to within said voids comprises growing scintillator material from a solution into said grid so as to fill the grid voids with scintillator material.

25. The method as claimed in claim 24, further comprising grinding or polishing extra scintillator material so as to achieve flat top and bottom surfaces.

26. The method as claimed in claim 18 wherein said providing a scintillator material to within said voids comprises growing scintillator material from a melt into said grid so as to fill the grid voids with scintillator material.

27. The method as claimed in claim 26, further comprising grinding or polishing extra scintillator material so as to achieve flat top and bottom surfaces.

28. The method as claimed in claim 18 wherein said providing a scintillator material to within said voids comprises pressing said grid into scintillator material plate under high temperature conditions so as to fill the grid voids with scintillator material, yet avoiding a complete meltdown of the scintillator material.

29. The method as claimed in claim 28, further comprising grinding or polishing extra scintillator material so as to achieve flat top and bottom surfaces.

30. The method as claimed in claim 18, wherein said providing a grid having voids comprises:
dicing parallel and vertical trenches in said scintillator material so as to receive a trenched scintillator; and
filing the trenched with adhesive material that forms said grid.

31. The method as claimed in claim 18 wherein said providing a scintillator material to within said voids comprises:
providing powder made of scintillator material;
pressing said powder of scintillator material into voids of said grid so as to fill the grid voids with scintillator material; and
pressing said powder into solid material by the effect of pressure and high temperature.

32. The method as claimed in claim 31, further comprising grinding or polishing extra scintillator material so as to achieve flat top and bottom surfaces.
